(19) United States
(12) Patent Application Publication
(10) Pub. No.: US 2018/0122566 A1
(43) Pub. Date: May 3, 2018

(54) TRANSFORMER SIMULATING CIRCUIT AND SIMULATING METHOD OF TRANSFORMER

(71) Applicant: JIANGSU LEADER ELECTRONICS INC., Zhenjiang City (CN)

(72) Inventor: Rene Frederik KOCH, New Taipei City (TW)

(73) Assignee: JIANGSU LEADER ELECTRONICS INC., Zhenjiang City (CN)

(21) Appl. No.: 15/342,651

(22) Filed: Nov. 3, 2016

(51) Int. Cl. H01F 38/08; H03H 7/00; G06F 17/50

(52) U.S. Cl. CPC H01F 38/08; G06F 17/5036; H03H 7/00

(57) ABSTRACT

A transformer simulating circuit includes a primary side, a secondary side, a first coupling capacitor, and a second coupling capacitor. The primary side includes a primary core-loss resistor, a primary intra-winding capacitor, and a magnetizing inductor connected in parallel, and includes a primary leakage inductor module connected between a primary winding and the primary intra-winding capacitor, and a primary winding resistor connected to the primary leakage inductor module. The secondary side includes a secondary leakage inductor module connected between a secondary winding and a secondary intra-winding capacitor, and a secondary winding resistor connected to the secondary leakage inductor module. The first coupling capacitor and the second coupling capacitor are connected between the primary side and the secondary side. Therefore, a simulated frequency response of the transformer simulating circuit is closer to a measured frequency response of a real transformer.

### BACKGROUND OF THE INVENTION

### 1. Field of the Invention

The present invention relates to a simulating circuit and a simulating method, and particularly to a transformer simulating circuit and a simulating method of a transformer.

### 2. Description of the Related Art

A physical transformer may be represented as a transformer simulating circuit that expresses electrical parameters of the physical transformer. With reference to FIG. 20, a conventional transformer simulating circuit may comprise a primary side and a secondary side.

The primary side of the conventional transformer simulating circuit may include a primary winding Wp, a primary winding resistor Rp, a primary leakage inductor Lpl, a primary core-loss resistor Rc, a primary intra-winding capacitor Cp, and a magnetizing inductor Lp.

The primary winding Wp, the primary core-loss resistor Rc, the primary intra-winding capacitor Cp, and the magnetizing inductor Lp are electronically connected in parallel. The primary winding resistor Rp and the primary leakage inductor Lpl are electronically connected in series. The primary winding Wp comprises a first terminal and a second terminal. The primary leakage inductor Lpl is electronically connected between the first terminal of the primary winding Wp and the primary winding resistor Rp.

The secondary side of the conventional transformer simulating circuit may include a secondary winding Ws, a secondary winding resistor Rs, a secondary leakage inductor Lsl, and a secondary intra-winding capacitor Cs. The secondary winding Ws and the secondary intra-winding capacitor Cs are electronically connected in parallel. The secondary leakage inductor Lsl and the secondary winding resistor Rs are electronically connected in series. The secondary winding Ws comprises a first terminal and a second terminal. The secondary leakage inductor Lsl is electronically connected between the first terminal of the secondary winding Ws and the secondary winding resistor.

The conventional transformer simulating circuit may further comprise a first coupling capacitor Cps1 and a second coupling capacitor Cps2. The first coupling capacitor Cps1 is electronically connected between the first terminal of the primary winding Wp and the first terminal of the secondary winding Ws. The second coupling capacitor Cps2 is electronically connected between the second terminal of the primary winding Wp and the second terminal of the secondary winding Ws.

The primary winding resistor Rp and the secondary winding resistor Rs respectively represent equivalent winding resistors of the primary winding Wp and the secondary winding Ws.

The core-loss resistor Rc represents an equivalent resistor of a result of a build-up and tear-down of magnetic field within a core of the transformer.

The primary intra-winding capacitor Cp and the secondary intra-winding capacitor Cs respectively represent equivalent capacitors within the primary winding Wp and the secondary winding Ws due to layered construction of the primary winding Wp and the secondary winding Ws.

The magnetizing inductor Lp is responsible for a creation of magnetic field. The first coupling capacitor Cps1 and the second coupling capacitor Cps2 represent the equivalent capacitive coupling between the primary winding Wp and the secondary winding Ws.

However, an error related to a location of a representation of the primary leakage inductor Lpl and the secondary leakage inductor Lsl may occur to the conventional transformer simulating circuit.

With reference to FIG. 21, a measured frequency response of a primary impedance of the physical transformer and a simulated frequency response of a primary impedance of the conventional transformer simulating circuit are shown. The measured frequency response is shown as a solid line Lp[P1S3], and the simulated frequency response is shown as a dashed line Lp[MOD1,P1S3].

A first self-resonance point f1s, such as a pole point, of the measured frequency response and a first self-resonance point f1s′ of the simulated frequency response are similar, but a second self-resonance point f2s , such as a zero point, of the measured frequency response and a second self-resonance point f2s′ of the simulated frequency response are different.

Difference between the second self-resonance points of the measured frequency response and the simulated frequency response is due to the fact that the conventional transformer simulating circuit has the secondary intra-winding capacitor Cs. The secondary intra-winding capacitor Cs is basically in parallel to the primary intra-winding capacitor Cp, therewith increasing the capacitor such that the second self-resonance points shifts a lower frequency.

With reference to FIG. 22, a measured frequency response of a primary leakage impedance of the physical transformer and a simulated frequency response of a primary leakage impedance of the conventional transformer simulating circuit are shown. The measured frequency response is shown as a solid line Lpl[P1S3], and the simulated frequency response is shown as a dashed line Lpl[MOD1,P1S3].

A first self-resonance point f3s, such as a pole point, of the measured frequency response and a first self-resonance point f3s′ of the simulated frequency response are different, and a second self-resonance point (not shown), such as a zero point, of the measured frequency response and the second self-resonance point fs′ of the simulated frequency response are different.

The conventional transformer simulating circuit models the primary leakage inductor Lpl in series with the magnetizing inductor Lp, therewith increasing the inductor such that the second self-resonance points shift a lower frequency.

Since the error (or mismatch) related to the location of a representation of the primary leakage inductor Lpl and the secondary leakage inductor Ls1 may occur, the conventional transformer simulating circuit needs to be improved.

### SUMMARY OF THE INVENTION

An objective of the present invention is to provide a transformer simulating circuit and a simulating method of a transformer.

The transformer simulating circuit comprises a primary side and a secondary side.

The primary side includes a primary winding, a primary winding resistor, a primary core-loss resistor, a primary intra-winding capacitor, a magnetizing inductor, and a primary leakage inductor module.

The primary core-loss resistor, the primary intra-winding capacitor, and the magnetizing inductor are electronically connected in parallel.

The primary leakage inductor module comprises a first end, a second end, a third end, and a fourth end. The first end and the second end of the primary leakage inductor module are respectively electronically connected to two ends of the primary intra-winding capacitor. The first end of the primary leakage inductor module is electronically connected to an end of the primary winding resistor.

The primary winding comprises a first terminal and a second terminal. The third end and the fourth end of the primary leakage inductor module are respectively electronically connected to the first terminal and the second terminal of the primary winding Wp.

The secondary side includes a secondary winding, a secondary winding resistor, a secondary intra-winding capacitor, and a secondary leakage inductor module.

The secondary winding is coupled with the primary winding, and comprises a first terminal and a second terminal.

The secondary leakage inductor module comprises a first end, a second end, a third end, and a fourth end. The first end and the second end of the secondary leakage inductor module are respectively electronically connected to the first terminal and the second terminal of the secondary winding Ws.

The secondary intra-winding capacitor Cs is electronically connected between the third end and the fourth end of the secondary leakage inductor module. The third end of the secondary leakage inductor module is further electronically connected to an end of the secondary winding resistor Rs.

The transformer simulating circuit further comprises a first coupling capacitor and a second coupling capacitor.

The first coupling capacitor is electronically connected between the first end of the primary leakage inductor module and the third end of the secondary leakage inductor module. The second coupling capacitor is electronically connected between the second end of the primary leakage inductor module and the fourth end of the secondary leakage inductor module.

Further the simulating method of the transformer comprises steps of:

providing a primary winding; wherein the primary winding comprises a first terminal and a second terminal;

providing a primary core-loss resistor;

providing a primary intra-winding capacitor;

providing a magnetizing inductor; wherein the magnetizing inductor is electronically connected to the primary core-loss resistor and the primary intra-winding capacitor in parallel;

providing a primary leakage inductor module; wherein the primary leakage inductor module comprises a first end, a second end, a third end, and a fourth end, the first end and the second end of the primary leakage inductor module are respectively electronically connected to two ends of the primary intra-winding capacitor, and the third end and the fourth end of the primary leakage inductor module are respectively electronically connected to the first terminal and the second terminal of the primary winding;

providing a primary winding resistor; wherein the primary winding resistor comprises an end electronically connected to the first end of the primary leakage inductor module;

providing a secondary winding resistor;

providing a secondary leakage inductor module; wherein the secondary leakage inductor module comprises a first end, a second end, a third end, and a fourth end, and the third end of the secondary leakage inductor module is electronically connected to an end of the secondary winding resistor;

providing a secondary winding; wherein the second winding is coupled with the primary winding, and comprises a first terminal and a second terminal; wherein the first terminal and the second terminal of the secondary winding are respectively electronically connected to the first end and the second end of the secondary leakage inductor;

providing a secondary intra-winding capacitor; wherein the secondary intra-winding capacitor is electronically connected between the third end and the fourth end of the secondary leakage inductor module;

providing a first coupling capacitor; wherein the first coupling capacitor is electronically connected between the first end of the primary leakage inductor module and the third end of the secondary leakage inductor module; and

providing a second coupling capacitor; wherein the second coupling capacitor is electronically connected between the second end of the primary leakage inductor module and the fourth end of the secondary leakage inductor module;

forming a transformer simulating circuit; and

implementing the transformer simulating circuit to simulate the transformer.

The primary leakage inductor module and the secondary leakage inductor module are represented as inductor parts that do not couple between the primary winding and the secondary winding, and leak magnetic flux. The leaked magnetic flux is the difference in magnetic flux between magnetic flux generated by the primary winding and magnetic flux that is responsible for the magnetic field experienced by the secondary winding.

The magnetic flux generated by the primary winding may not change, no matter how the secondary winding is coupled to the primary winding. When the secondary winding opposes the magnetic flux more, the leaked magnetic flux may increase, therewith reducing the magnetic flux that couples both primary winding and the secondary winding.

Therefore, a conventional transformer simulating circuit is redesigned, and a simulated frequency response of a primary impedance of the transformer simulating circuit may be closer to a measured frequency response of a primary impedance of a real transformer.

Other objectives, advantages and novel features of the invention will become more apparent from the following detailed description when taken in conjunction with the accompanying drawings.

### BRIEF DESCRIPTION OF THE DRAWINGS

FIG. 1 is a circuit diagram of a transformer simulating circuit;

FIGS. 2 to 16 are circuit diagrams of the first to fifteenth embodiments of the transformer simulating circuit;

FIG. 17 is a diagram of measured frequency response of a primary impedance of the transformer and a simulated frequency response of a primary impedance of the transformer simulating circuit;

FIG. 18 is a diagram of measured frequency response of a primary leakage impedance of the transformer and a simulated frequency response of a primary leakage impedance of the transformer simulating circuit;

FIG. 19 is a flowchart of a simulating method of a transformer simulating circuit;

FIG. 20 is a circuit diagram of a conventional transformer simulating circuit;

FIG. 21 is a diagram of measured frequency response of a primary impedance of the conventional transformer and a simulated frequency response of a primary impedance of the conventional transformer simulating circuit; and

FIG. 22 is a diagram of measured frequency response of a primary leakage impedance of the conventional transformer and a simulated frequency response of a primary leakage impedance of the conventional transformer simulating circuit.

### DETAILED DESCRIPTION OF THE INVENTION

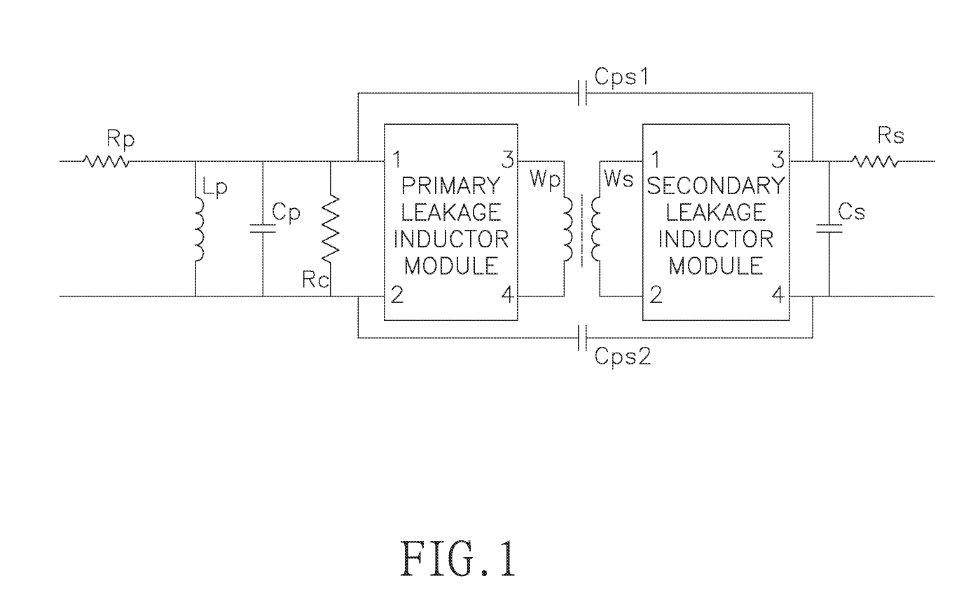

The simulating method and the transformer simulating circuit of the present invention are performed in simulating software, such as the Pspice or the Hspcice, of a computer. With reference to FIG. 1, the present invention is a transformer simulating circuit and a simulating method of a transformer.

The transformer simulating circuit comprises a primary side and a secondary side.

The primary side includes a primary winding Wp, a primary winding resistor Rp, a primary core-loss resistor Re, a primary intra-winding capacitor Cp, a magnetizing inductor Lp, and a primary leakage inductor module.

The primary core-loss resistor Rc, the primary intra-winding capacitor Cp, and the magnetizing inductor Lp are electronically connected in parallel.

The primary leakage inductor module comprises a first end, a second end, a third end, and a fourth end. The first end and the second end of the primary leakage inductor module are respectively electronically connected to two ends of the primary intra-winding capacitor Cp. The first end of the primary leakage inductor module is electronically connected to an end of the primary winding resistor Rp.

The primary winding Wp comprises a first terminal and a second terminal. The third end and the fourth end of the primary leakage inductor module are respectively electronically connected to the first terminal and the second terminal of the primary winding Wp.

The secondary side includes a secondary winding Ws, a secondary winding resistor Rs, a secondary intra-winding capacitor Cs, and a secondary leakage inductor module.

The secondary winding Ws is coupled with the primary winding Wp, and comprises a first terminal and a second terminal.

The secondary leakage inductor module comprises a first end, a second end, a third end, and a fourth end. The first end and the second end of the secondary leakage inductor module are respectively electronically connected to the first terminal and the second terminal of the secondary winding Ws.

The secondary intra-winding capacitor Cs is electronically connected between the third end and the fourth end of the secondary leakage inductor module. The third end of the secondary leakage inductor module is further electronically connected to an end of the secondary winding resistor Rs.

The transformer simulating circuit further comprises a first coupling capacitor Cps1 and a second coupling capacitor Cps2.

The first coupling capacitor Cps1 is electronically connected between the first end of the primary leakage inductor module and the third end of the secondary leakage inductor module. The second coupling capacitor Cps2 is electronically connected between the second end of the primary leakage inductor module and the fourth end of the secondary leakage inductor module.

The primary leakage inductor module and the secondary leakage inductor module are represented as inductor parts that do not couple between the primary winding Wp and the secondary winding Ws, and leak magnetic flux.

The leaked magnetic flux is the difference in magnetic flux between magnetic flux generated by the primary winding Wp and magnetic flux that is responsible for the magnetic field experienced by the secondary winding Ws.

The magnetic flux generated by the primary winding Wp may not change, no matter how the secondary winding Ws is coupled to the primary winding Wp. When the secondary winding Ws opposes the magnetic flux more, the leaked magnetic flux may increase, therewith reducing the magnetic flux that couples both primary winding and the secondary winding.

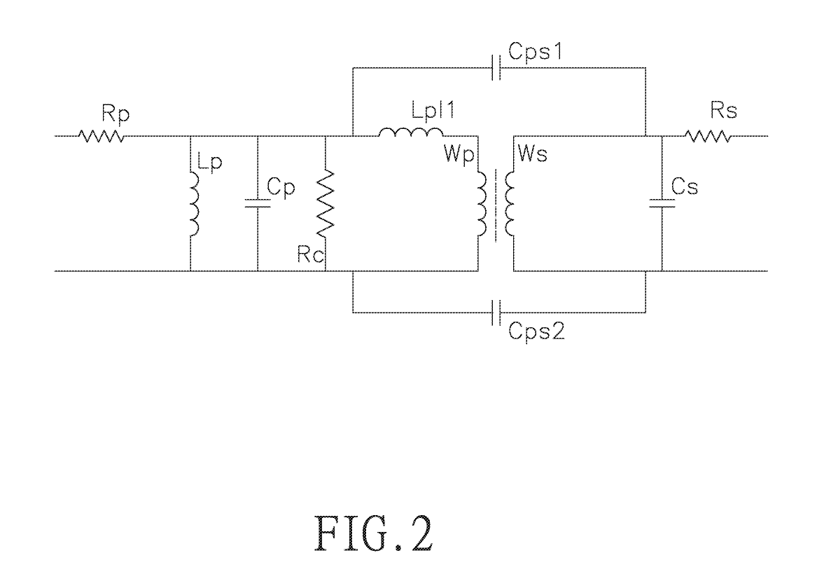

With reference to FIG. 2, a first embodiment of the transformer simulating circuit is shown. In the first embodiment, the primary leakage inductor module comprises a first primary leakage inductor Lpl1.

The first primary leakage inductor Lpl1 is electronically connected between the first end and the third end of the primary leakage inductor module. The second end and the fourth end of the primary leakage inductor module are electronically connected together.

The first end and the third end of the secondary leakage inductor module are electronically connected together. The second end and the fourth end of the secondary leakage inductor module are electronically connected together.

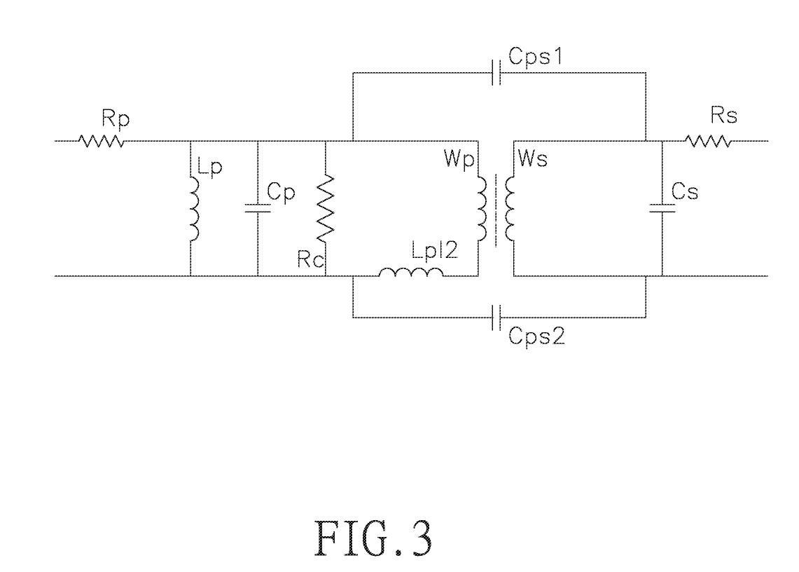

With reference to FIG. 3, a second embodiment of the transformer simulating circuit is shown. In the second embodiment, the primary leakage inductor module comprises a second primary leakage inductor Lpl2.

The second primary leakage inductor Lpl2 is electronically connected between the second end and the fourth end of the primary leakage inductor module. The first end and the third end of the primary leakage inductor module are electronically connected together.

The first end and the third end of the secondary leakage inductor module are electronically connected together. The second end and the fourth end of the secondary leakage inductor module are electronically connected together.

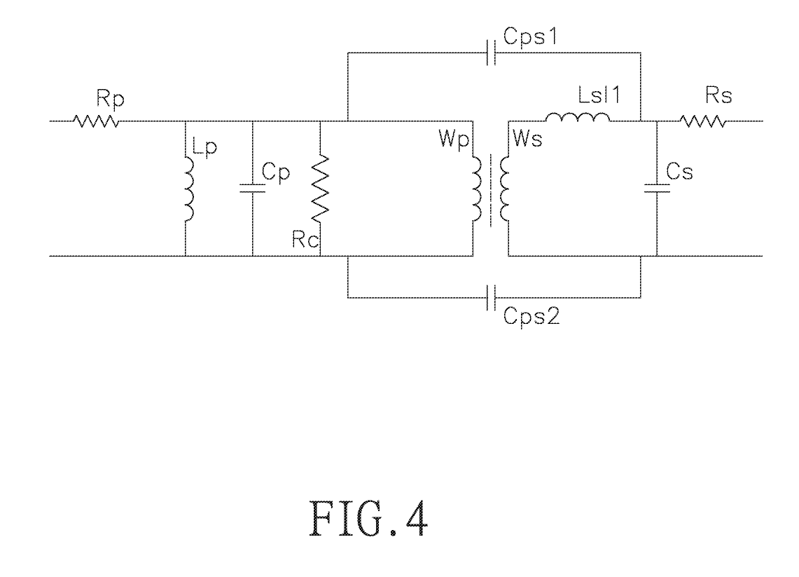

With reference to FIG. 4, a third embodiment of the transformer simulating circuit is shown. In the third embodiment, the secondary leakage inductor module comprises a first secondary leakage inductor Lsl1.

The first end and the third end of the primary leakage inductor module are electronically connected together. The second end and the fourth end of the primary leakage inductor module are electronically connected together.

The first secondary leakage inductor Lsl1 is electronically connected between the first end and the third end of the secondary leakage inductor module. The second end and the fourth end of the secondary leakage inductor module are electronically connected together.

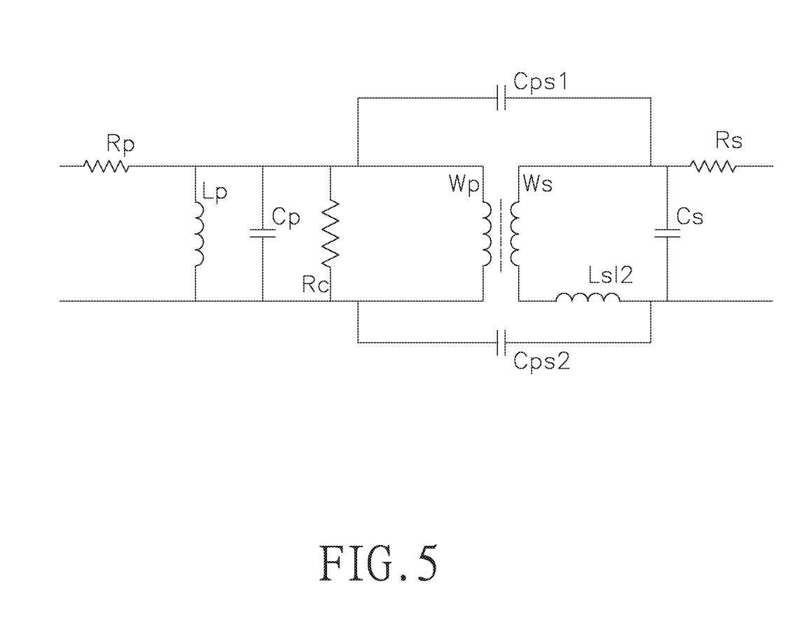

With reference to FIG. 5, a fourth embodiment of the transformer simulating circuit is shown. In the fourth embodiment, the secondary leakage inductor module comprises a second primary leakage inductor Lsl2.

The first end and the third end of the primary leakage inductor module are electronically connected together. The second end and the fourth end of the primary leakage inductor module are electronically connected together.

The second secondary leakage inductor Lsl2 is electronically connected between the second end and the fourth end of the secondary leakage inductor module. The first end and the third end of the secondary leakage inductor module are electronically connected together.

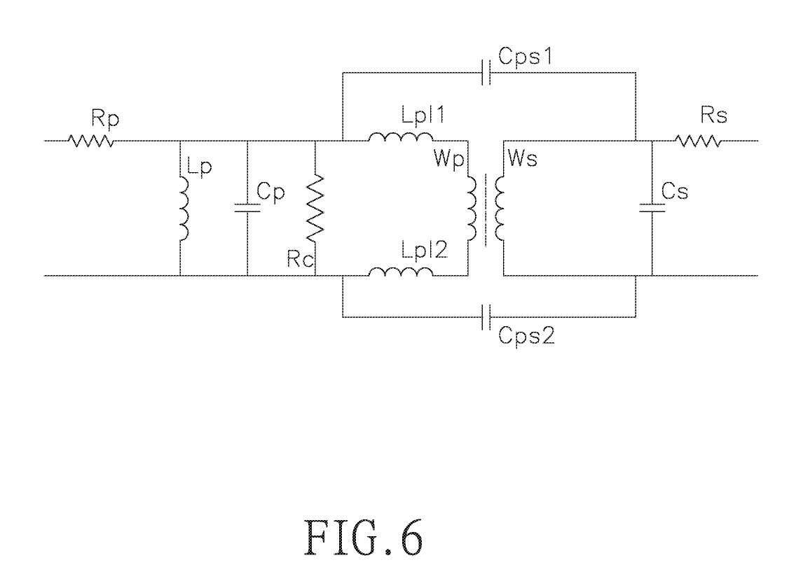

With reference to FIG. 6, a fifth embodiment of the transformer simulating circuit is shown. In the fifth embodiment, the primary leakage inductor module comprises a first primary leakage inductor Lpl1 and a second primary leakage inductor Lpl2.

The first primary leakage inductor Lpl1 is electronically connected between the first end and the third end of the primary leakage inductor module. The second primary leakage inductor Lpl2 is electronically connected between the second end and the fourth end of the primary leakage inductor module.

The first end and the third end of the secondary leakage inductor module are electronically connected together. The second end and the fourth end of the secondary leakage inductor module are electronically connected together.

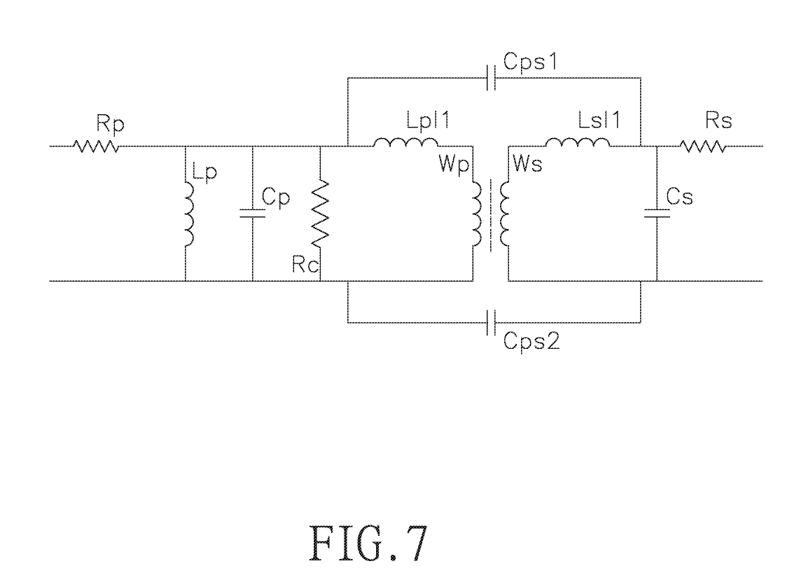

With reference to FIG. 7, a sixth embodiment of the transformer simulating circuit is shown. In the sixth embodiment, the primary leakage inductor module comprises a first primary leakage inductor Lpl1, and the secondary leakage inductor module comprises a first secondary leakage inductor Lsl1.

The first primary leakage inductor Lpl1 is electronically connected between the first end and the third end of the primary leakage inductor module. The second end and the fourth end of the primary leakage inductor module are electronically connected together.

The first secondary leakage inductor Lsl1 is electronically connected between the first end and the third end of the secondary leakage inductor module. The second end and the fourth end of the secondary leakage inductor module are electronically connected together.

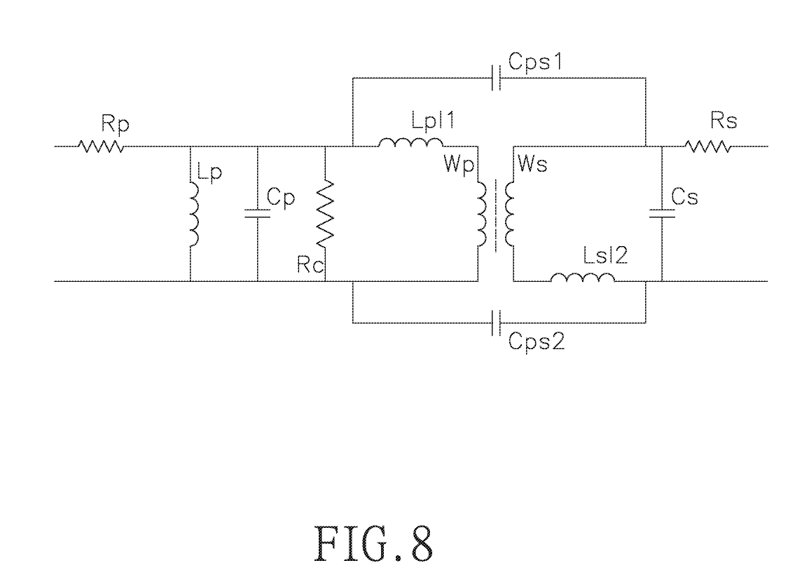

With reference to FIG. 8, a seventh embodiment of the transformer simulating circuit is shown. In the seventh embodiment, the primary leakage inductor module comprises a first primary leakage inductor Lpl1, and the secondary leakage inductor module comprises a second secondary leakage inductor Lsl2.

The first primary leakage inductor Lpl1 is electronically connected between the first end and the third end of the primary leakage inductor module. The second end and the fourth end of the primary leakage inductor module are electronically connected together.

The first end and the third end of the secondary leakage inductor module are electronically connected together. The second secondary leakage inductor Lsl2 is electronically connected between the second end and the fourth end of the secondary leakage inductor module.

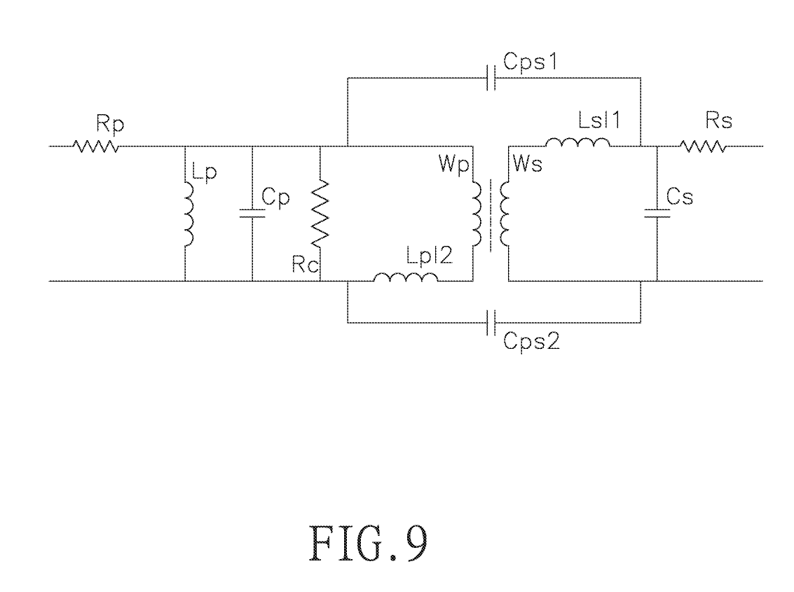

With reference to FIG. 9, an eighth embodiment of the transformer simulating circuit is shown. In the eighth embodiment, the primary leakage inductor module comprises a second primary leakage inductor Lpl2, and the secondary leakage inductor module comprises a first secondary leakage inductor Lsl1.

The first end and the third end of the primary leakage inductor module are electronically connected together. The second primary leakage inductor Lpl2 is electronically connected between the second end and the fourth end of the primary leakage inductor module.

The first secondary leakage inductor Lsl1 is electronically connected between the first end and the third end of the secondary leakage inductor module. The second end and the fourth end of the secondary leakage inductor module are electronically connected together.

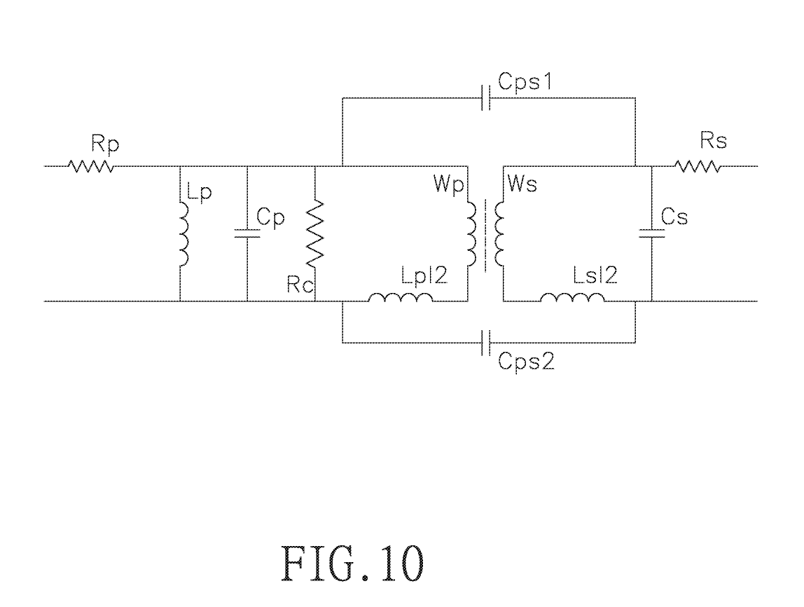

With reference to FIG. 10, a ninth embodiment of the transformer simulating circuit is shown. In the ninth embodiment, the primary leakage inductor module comprises a second primary leakage inductor Lpl2, and the secondary leakage inductor module comprises a second secondary leakage inductor Lsl2.

The first end and the third end of the primary leakage inductor module are electronically connected together. The second primary leakage inductor Lpl2 is electronically connected between the second end and the fourth end of the primary leakage inductor module.

The first end and the third end of the secondary leakage inductor module are electronically connected together. The second secondary leakage inductor Lsl2 is electronically connected between the second end and the fourth end of the secondary leakage inductor module.

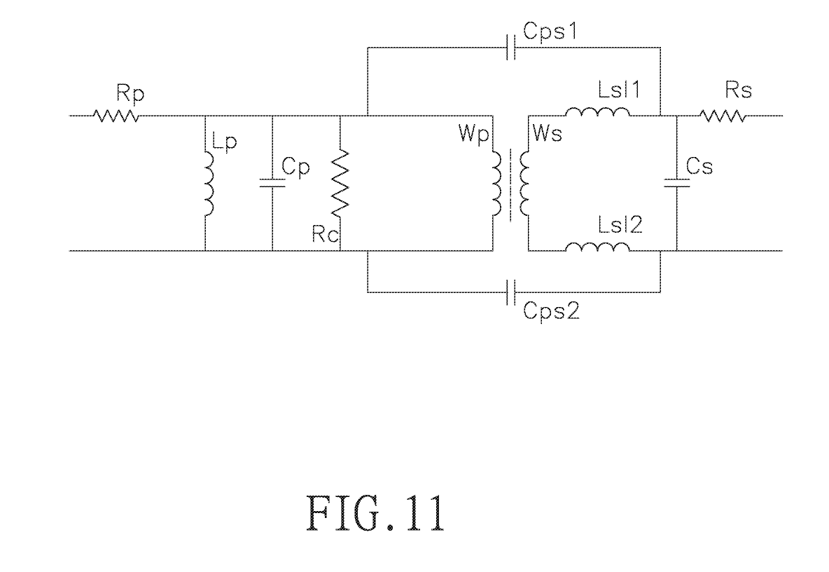

With reference to FIG. 11, a tenth embodiment of the transformer simulating circuit is shown. In the tenth embodiment, the secondary leakage inductor module comprises a first secondary leakage inductor Lsl1 and a second secondary leakage inductor Lsl2.

The first end and the third end of the primary leakage inductor module are electronically connected together. The second end and the fourth end of the primary leakage inductor module are electronically connected together.

The first secondary leakage inductor Lsl1 is electronically connected between the first end and the third end of the secondary leakage inductor module. The second secondary leakage inductor Lsl2 is electronically connected between the second end and the fourth end of the secondary leakage inductor module.

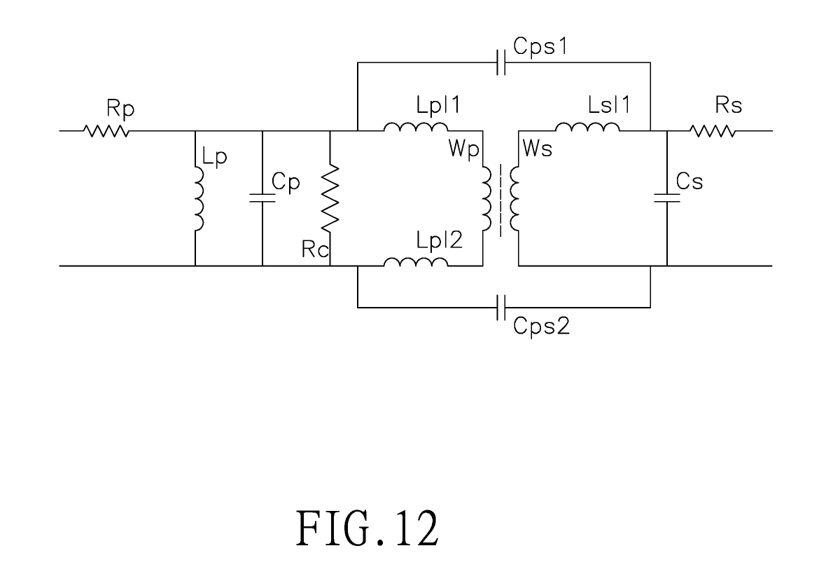

With reference to FIG. 12, an eleventh embodiment of the transformer simulating circuit is shown. In the eleventh embodiment, the primary leakage inductor module comprises a first primary leakage inductor Lpl1 and a second primary leakage inductor Lpl2, and the secondary leakage inductor module comprises a first secondary leakage inductor Lsl1.

The first primary leakage inductor Lpl1 is electronically connected between the first end and the third end of the primary leakage inductor module. The second primary leakage inductor Lpl2 is electronically connected between the second end and the fourth end of the primary leakage inductor module.

The first secondary leakage inductor Lsl1 is electronically connected between the first end and the third end of the secondary leakage inductor module. The second end and the fourth end of the secondary leakage inductor module are electronically connected together.

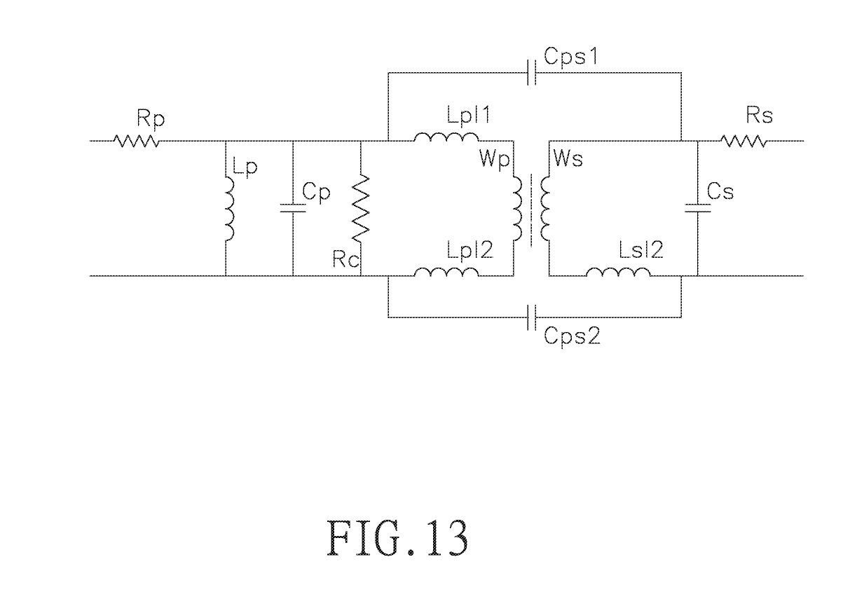

With reference to FIG. 13, a twelfth embodiment of the transformer simulating circuit is shown. In the twelfth embodiment, the primary leakage inductor module comprises a first primary leakage inductor Lpl1 and a second primary leakage inductor Lpl2, and the secondary leakage inductor module comprises a second secondary leakage inductor Lsl2.

The first primary leakage inductor Lpl1 is electronically connected between the first end and the third end of the primary leakage inductor module. The second primary leakage inductor Lpl2 is electronically connected between the second end and the fourth end of the primary leakage inductor module.

The first end and the third end of the secondary leakage inductor module are electronically connected together. The second secondary leakage inductor Lsl2 is electronically connected between the second end and the fourth end of the secondary leakage inductor module.

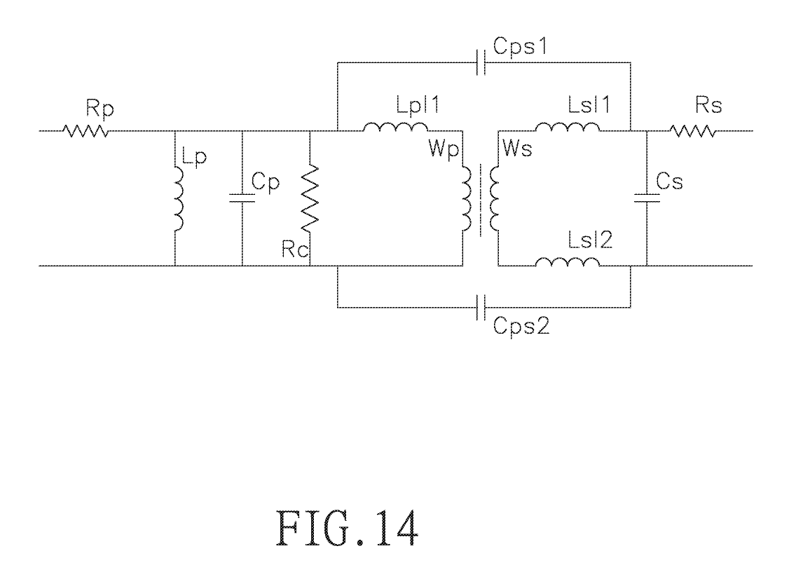

With reference to FIG. 14, a thirteenth embodiment of the transformer simulating circuit is shown. In the thirteenth embodiment, the primary leakage inductor module comprises a first primary leakage inductor Lpl1, and the secondary leakage inductor module comprises a first secondary leakage inductor Lsl1 and a second secondary leakage inductor Lsl2.

The first primary leakage inductor Lpl1 is electronically connected between the first end and the third end of the primary leakage inductor module. The second end and the fourth end of the primary leakage inductor module are electronically connected together.

The first secondary leakage inductor Lsl1 is electronically connected between the first end and the third end of the secondary leakage inductor module. The second secondary leakage inductor Lsl2 is electronically connected between the second end and the fourth end of the secondary leakage inductor module.

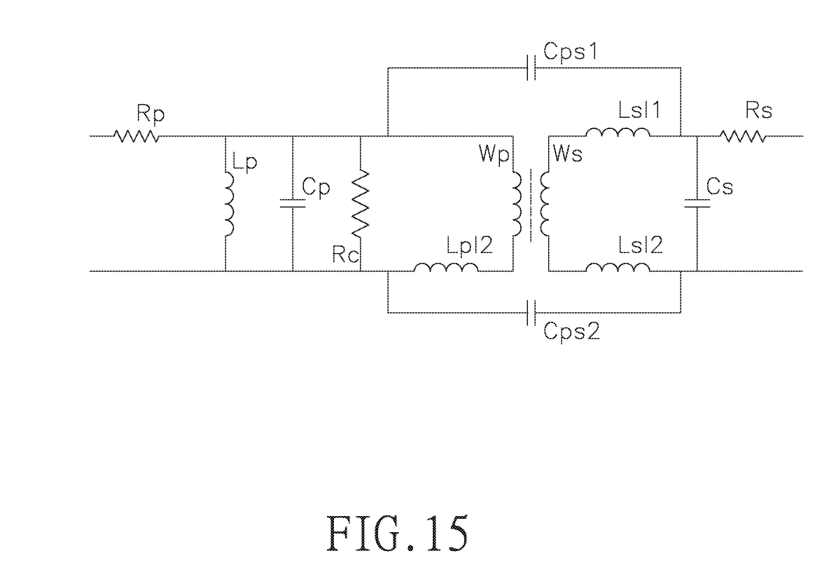

With reference to FIG. 15, a fourteenth embodiment of the transformer simulating circuit is shown. In the fourteenth embodiment, the primary leakage inductor module comprises a second primary leakage inductor Lpl2, and the secondary leakage inductor module comprises a first secondary leakage inductor Lsl1 and a second secondary leakage inductor Lsl2.

The first end and the third end of the primary leakage inductor module are electronically connected together. The second primary leakage inductor Lpl2 is electronically connected between the second end and the fourth end of the primary leakage inductor module.

The first secondary leakage inductor Lsl1 is electronically connected between the first end and the third end of the secondary leakage inductor module. The second secondary leakage inductor Lsl2 is electronically connected between the second end and the fourth end of the secondary leakage inductor module.

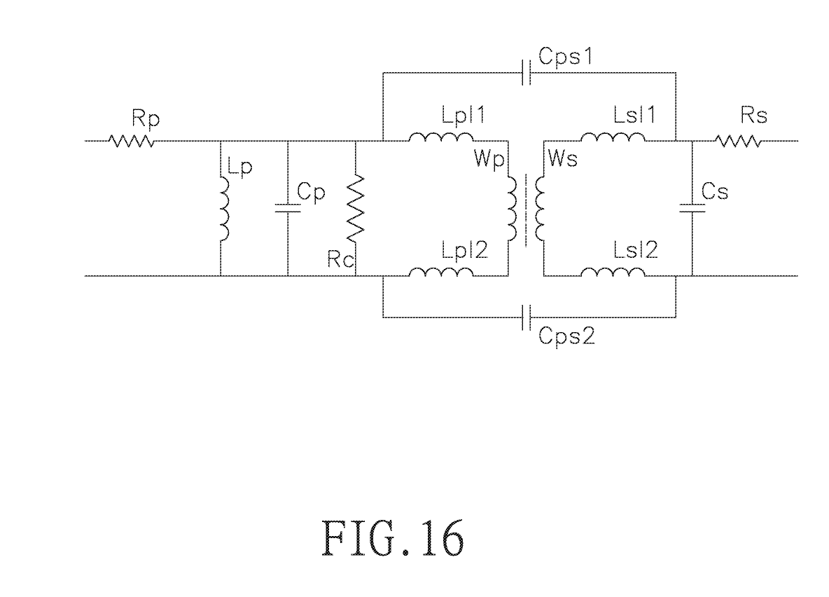

With reference to FIG. 16, a fifteenth embodiment of the transformer simulating circuit is shown. In the fifteenth embodiment, the primary leakage inductor module comprises a first primary leakage inductor Lpl1 and a second primary leakage inductor Lpl2, and the secondary leakage inductor module comprises a first secondary leakage inductor Lsl1 and a second secondary leakage inductor Lsl2.

The first primary leakage inductor Lpl1 is electronically connected between the first end and the third end of the primary leakage inductor module. The second primary leakage inductor Lpl2 is electronically connected between the second end and the fourth end of the primary leakage inductor module.

The first secondary leakage inductor Lsl1 is electronically connected between the first end and the third end of the secondary leakage inductor module. The second secondary leakage inductor Lsl2 is electronically connected between the second end and the fourth end of the secondary leakage inductor module.

Take the third embodiment shown in FIG. 4 for an example, the first secondary leakage inductor Lsl1 has clearly shifted to be in-between any of the primary parasitic components. The first secondary leakage inductor Lsl1 is intentionally drawn on the secondary side, as a higher frequency self-resonance point is due to the first secondary leakage inductor Lsl1 in combination with the secondary intra-winding capacitor Cs. Reflecting all components to the primary side, by turn-ratio may not result in the same frequency characteristics.

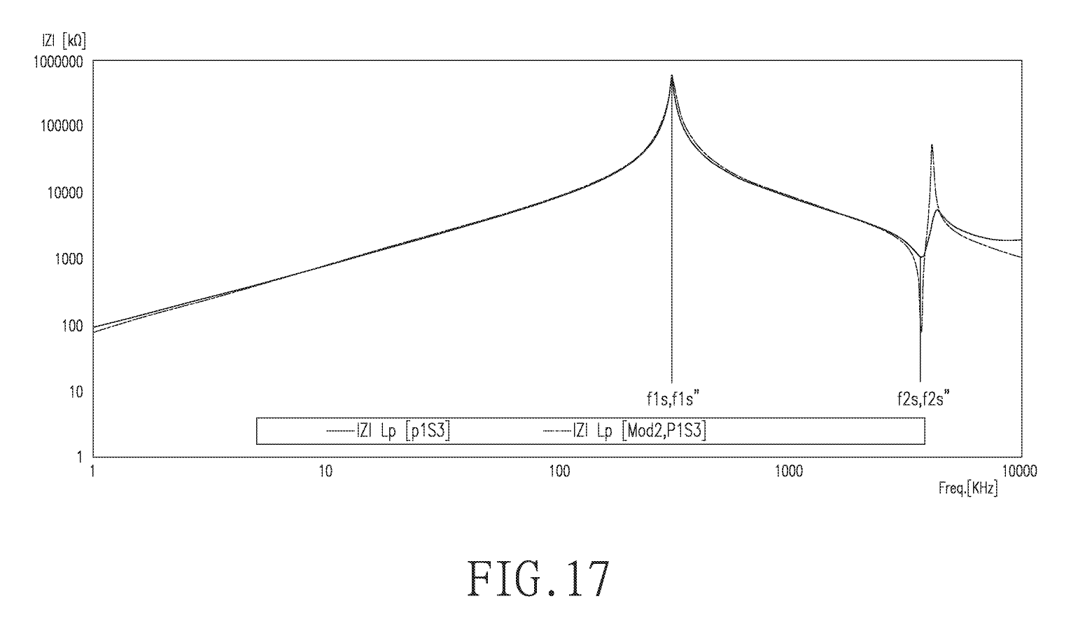

With reference to FIG. 17, a measured frequency response of a primary impedance of a conventional transformer and a simulated frequency response of a primary impedance of the transformer simulating circuit are shown. The measured frequency response is shown as a solid line Lp[P1S3], and the simulated frequency response is shown as a dashed line Lp[MOD2,P1S3].

A first self-resonance point f1s, such as a pole point, of the measured frequency response and a first self-resonance point f1s″ of the simulated frequency response are similar, and a second self-resonance point f2s, such as a zero point, of the measured frequency response and a second self-resonance point f2s″ of the simulated frequency response are also similar.

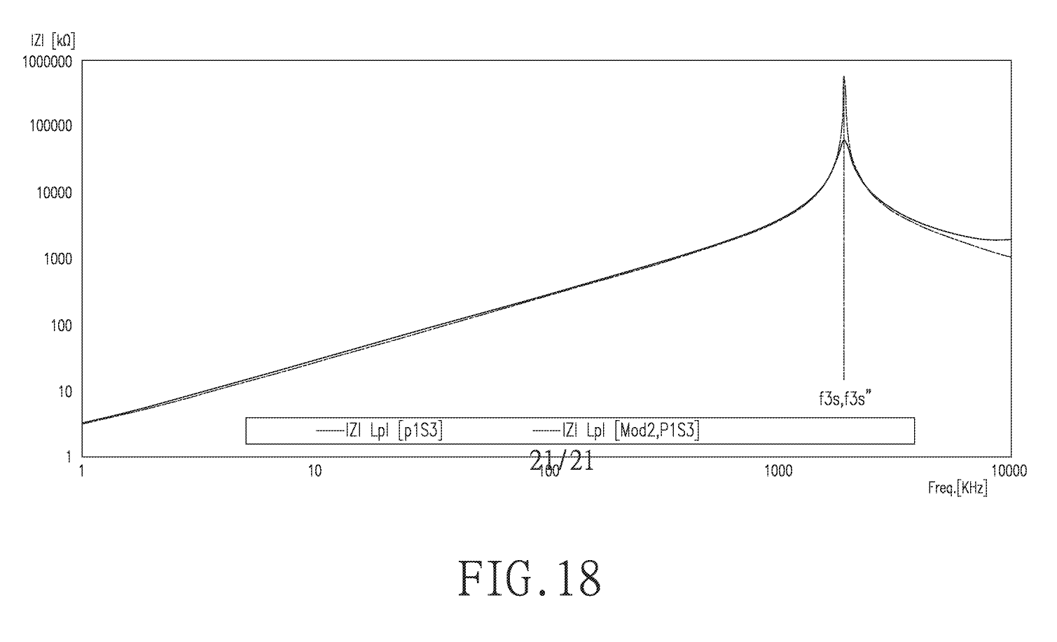

With reference to FIG. 18, a measured frequency response of a primary leakage impedance of the conventional transformer and a simulated frequency response of a primary leakage impedance of the transformer simulating circuit are shown. The measured frequency response is shown as a solid line Lpl[P1S3], and the simulated frequency response is shown as a dashed line Lpl[MOD2,P1S3].

A first self-resonance point f3s, such as a pole point, of the measured frequency response and a first self-resonance point f3s″ of the simulated frequency response are similar.

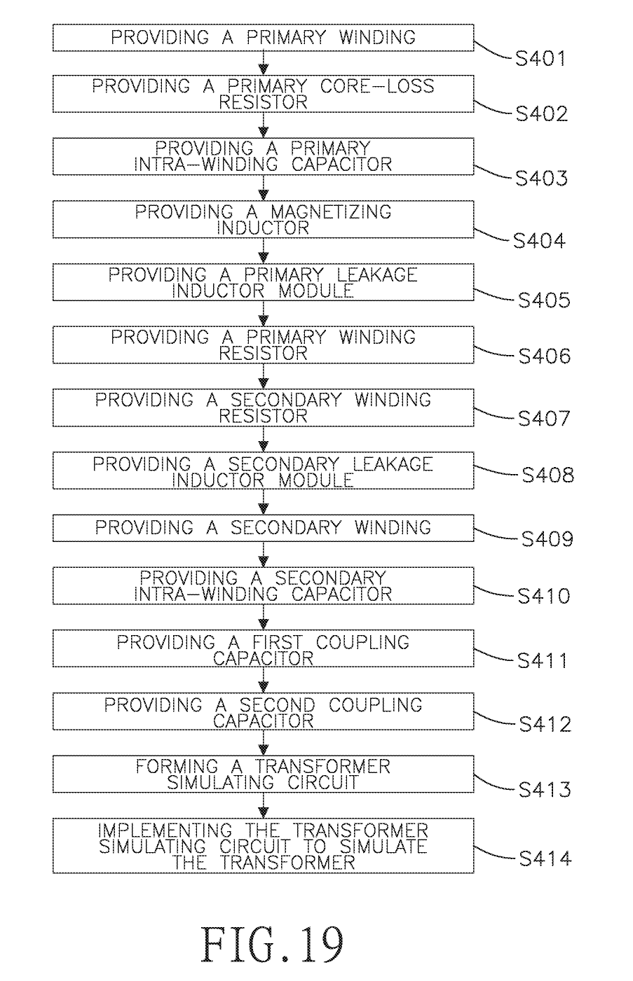

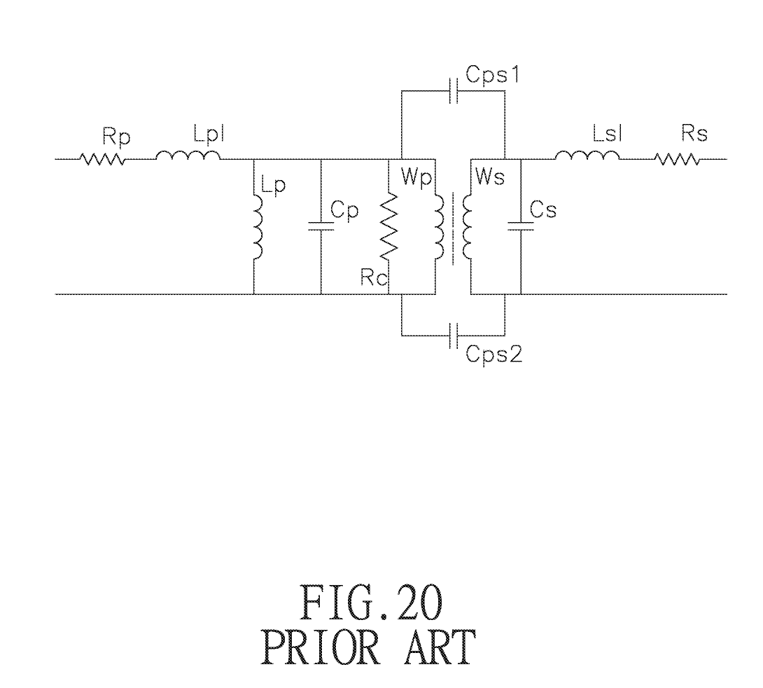

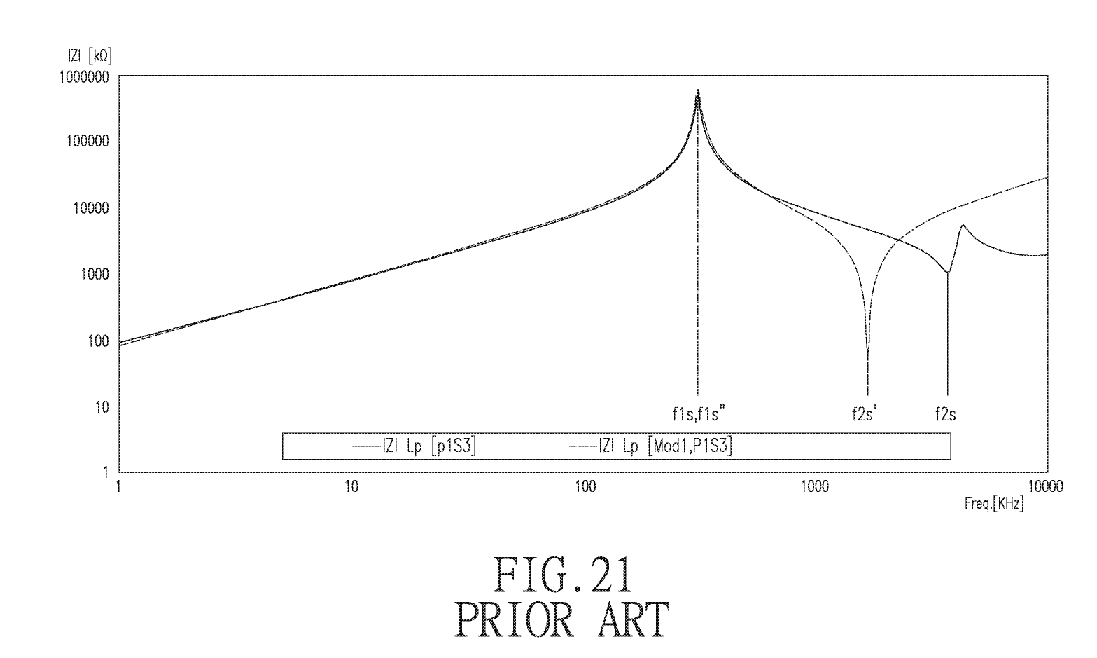

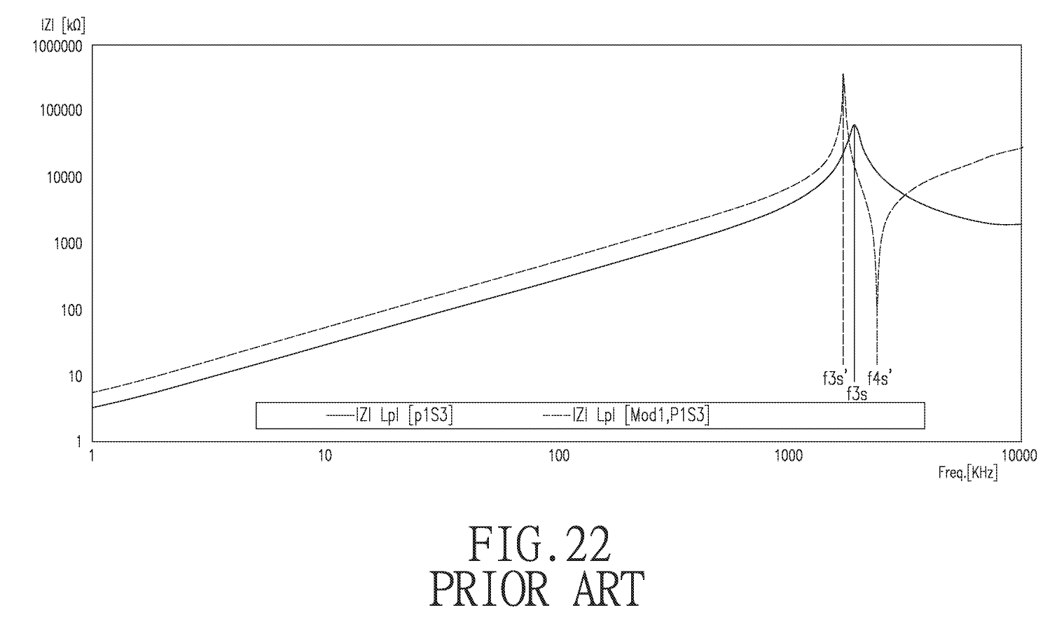

Further, with reference to FIG. 19, the simulating method of a transformer, comprises steps of:

providing a primary winding (S401); wherein the primary winding comprises a first terminal and a second terminal;

providing a primary core-loss resistor (S402);

providing a primary intra-winding capacitor (S403);

providing a magnetizing inductor (S404); wherein the magnetizing inductor is electronically connected to the primary core-loss resistor and the primary intra-winding capacitor in parallel;

providing a primary leakage inductor module (S405); wherein the primary leakage inductor module comprises a first end, a second end, a third end, and a fourth end, the first end and the second end of the primary leakage inductor module are respectively electronically connected to two ends of the primary intra-winding capacitor, and the third end and the fourth end of the primary leakage inductor module are respectively electronically connected to the first terminal and the second terminal of the primary winding;

providing a primary winding resistor (S406); wherein the primary winding resistor comprises an end electronically connected to the first end of the primary leakage inductor module;

providing a secondary winding resistor (S407);

providing a secondary leakage inductor module (S408); wherein the secondary leakage inductor module comprises a first end, a second end, a third end, and a fourth end, and the third end of the secondary leakage inductor module is electronically connected to an end of the secondary winding resistor;

providing a secondary winding (S409); wherein the secondary winding is coupled with the primary winding, and comprises a first terminal and a second terminal; wherein the first terminal and the second terminal of the secondary winding are respectively electronically connected to the first end and the second end of the secondary leakage inductor;

providing a secondary intra-winding capacitor (S410); wherein the secondary intra-winding capacitor is electronically connected between the third end and the fourth end of the secondary leakage inductor module;

providing a first coupling capacitor (S411); wherein the first coupling capacitor is electronically connected between the first end of the primary leakage inductor module and the third end of the secondary leakage inductor module; and

providing a second coupling capacitor (S412); wherein the second coupling capacitor is electronically connected between the second end of the primary leakage inductor module and the fourth end of the secondary leakage inductor module;

forming a transformer simulating circuit (S413); and

implementing the transformer simulating circuit to simulate the transformer (S414).

Therefore, a conventional transformer simulating circuit is redesigned, and a simulated frequency response of a primary impedance of the transformer simulating circuit may be closer to a measured frequency response of a primary impedance of a transformer.

The primary leakage inductor module and the secondary leakage inductor module are illustrated with the first embodiment to the fifteenth embodiment of the transformer simulating circuit described above in FIGS. 2 to 16.

Due to the primary leakage inductor module and the secondary leakage inductor module in different embodiments of the transformer simulating circuit, all transfer calculations, especially those where the primary leakage inductor module and the secondary leakage inductor module are part of the transfer function, need to be re-evaluated and probably changed. This therefore has a reasonable impact on resonant converters and how the primary leakage inductor module and the secondary leakage inductor module are implemented is part of the energy transfer.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A transformer simulating circuit, comprising:
a primary side, comprising:
a primary core-loss resistor;
a primary intra-winding capacitor;
a magnetizing inductor; wherein the magnetizing inductor, the primary core-loss resistor, and the primary intra-winding capacitor are electronically connected in parallel; and
a primary leakage inductor module, comprising a first end, a second end, a third end, and a fourth end; wherein the first end and the second end of the primary leakage inductor module are respectively electronically connected to two ends of the primary intra-winding capacitor;
a primary winding, comprising a first terminal and a second terminal;
wherein the first terminal and the second terminal of the primary winding are respectively electronically connected to the third end and the fourth end of the primary leakage inductor module; and
a primary winding resistor, comprising an end electronically connected to the first end of the primary leakage inductor module;
a secondary side, comprising:
a secondary winding resistor;
a secondary leakage inductor module, comprising a first end, a second end, a third end, and a fourth end; wherein the third end of the secondary leakage inductor module is electronically connected to an end of the secondary winding resistor;
a secondary winding, coupled with the primary winding, and comprising a first terminal and a second terminal; wherein the first terminal and the second terminal of the secondary winding are respectively electronically connected to the first end and the second end of the secondary leakage inductor module; and
a secondary intra-winding capacitor, electronically connected between the third end and the fourth end of the secondary leakage inductor module;
a first coupling capacitor, electronically connected between the first end of the primary leakage inductor module and the third end of the secondary leakage inductor module; and
a second coupling capacitor, electronically connected between the second end of the primary leakage inductor module and the fourth end of the secondary leakage inductor module.

2. The transformer simulating circuit as claimed in claim 1, wherein:
the primary leakage inductor module comprises a first primary leakage inductor;
the first primary leakage inductor is electronically connected between the first end and the third end of the primary leakage inductor module;
the second end and the fourth end of the primary leakage inductor module are electronically connected together;
the first end and the third end of the secondary leakage inductor module are electronically connected together;
the second end and the fourth end of the secondary leakage inductor module are electronically connected together.

3. The transformer simulating circuit as claimed in claim 1, wherein:
the primary leakage inductor module comprises a second primary leakage inductor;
the second primary leakage inductor is electronically connected between the second end and the fourth end of the primary leakage inductor module;
the first end and the third end of the primary leakage inductor module are electronically connected together;
the first end and the third end of the secondary leakage inductor module are electronically connected together;
the second end and the fourth end of the secondary leakage inductor module are electronically connected together.

4. The transformer simulating circuit as claimed in claim 1, wherein:
the secondary leakage inductor module comprises a first secondary leakage inductor;
the first end and the third end of the primary leakage inductor module are electronically connected together;
the second end and the fourth end of the primary leakage inductor module are electronically connected together;
the first secondary leakage inductor is electronically connected between the first end and the third end of the secondary leakage inductor module;
the second end and the fourth end of the secondary leakage inductor module are electronically connected together.

5. The transformer simulating circuit as claimed in claim 1, wherein:
the secondary leakage inductor module comprises a second primary leakage inductor;
the first end and the third end of the primary leakage inductor module are electronically connected together;
the second end and the fourth end of the primary leakage inductor module are electronically connected together;
the second secondary leakage inductor is electronically connected between the second end and the fourth end of the secondary leakage inductor module;
the first end and the third end of the secondary leakage inductor module are electronically connected together.

6. The transformer simulating circuit as claimed in claim 1, wherein:
the primary leakage inductor module comprises a first primary leakage inductor and a second primary leakage inductor;
the first primary leakage inductor is electronically connected between the first end and the third end of the primary leakage inductor module;
the second primary leakage inductor is electronically connected between the second end and the fourth end of the primary leakage inductor module;
the first end and the third end of the secondary leakage inductor module are electronically connected together;
the second end and the fourth end of the secondary leakage inductor module are electronically connected together.

7. The transformer simulating circuit as claimed in claim 1, wherein:
the primary leakage inductor module comprises a first primary leakage inductor;
the secondary leakage inductor module comprises a first secondary leakage inductor;
the first primary leakage inductor is electronically connected between the first end and the third end of the primary leakage inductor module;
the second end and the fourth end of the primary leakage inductor module are electronically connected together;
the first secondary leakage inductor is electronically connected between the first end and the third end of the secondary leakage inductor module;
the second end and the fourth end of the secondary leakage inductor module are electronically connected together.

8. The transformer simulating circuit as claimed in claim 1, wherein:
the primary leakage inductor module comprises a first primary leakage inductor;
the secondary leakage inductor module comprises a second secondary leakage inductor;
the first primary leakage inductor is electronically connected between the first end and the third end of the primary leakage inductor module;
the second end and the fourth end of the primary leakage inductor module are electronically connected together;
the first end and the third end of the secondary leakage inductor module are electronically connected together;
the second secondary leakage inductor is electronically connected between the second end and the fourth end of the secondary leakage inductor module.

9. The transformer simulating circuit as claimed in claim 1, wherein:
the primary leakage inductor module comprises a second primary leakage inductor;
the secondary leakage inductor module comprises a first secondary leakage inductor;
the first end and the third end of the primary leakage inductor module are electronically connected together;
the second primary leakage inductor is electronically connected between the second end and the fourth end of the primary leakage inductor module;
the first secondary leakage inductor is electronically connected between the first end and the third end of the secondary leakage inductor module;
the second end and the fourth end of the secondary leakage inductor module are electronically connected together.

10. The transformer simulating circuit as claimed in claim 1, wherein:
the primary leakage inductor module comprises a second primary leakage inductor;
the secondary leakage inductor module comprises a second secondary leakage inductor;
the first end and the third end of the primary leakage inductor module are electronically connected together;
the second primary leakage inductor is electronically connected between the second end and the fourth end of the primary leakage inductor module;
the first end and the third end of the secondary leakage inductor module are electronically connected together;
the second secondary leakage inductor is electronically connected between the second end and the fourth end of the secondary leakage inductor module.

11. The transformer simulating circuit as claimed in claim 1, wherein:
the secondary leakage inductor module comprises a first secondary leakage inductor and a second secondary leakage inductor;
the first end and the third end of the primary leakage inductor module are electronically connected together;
the second end and the fourth end of the primary leakage inductor module are electronically connected together;
the first secondary leakage inductor is electronically connected between the first end and the third end of the secondary leakage inductor module;
the second secondary leakage inductor is electronically connected between the second end and the fourth end of the secondary leakage inductor module.

12. The transformer simulating circuit as claimed in claim 1, wherein:
the primary leakage inductor module comprises a first primary leakage inductor and a second primary leakage inductor;
the secondary leakage inductor module comprises a first secondary leakage inductor;
the first primary leakage inductor is electronically connected between the first end and the third end of the primary leakage inductor module;
the second primary leakage inductor is electronically connected between the second end and the fourth end of the primary leakage inductor module;
the first secondary leakage inductor is electronically connected between the first end and the third end of the secondary leakage inductor module;
the second end and the fourth end of the secondary leakage inductor module are electronically connected together.

13. The transformer simulating circuit as claimed in claim 1, wherein:
the primary leakage inductor module comprises a first primary leakage inductor and a second primary leakage inductor, and the secondary leakage inductor module comprises a second secondary leakage inductor;
the first primary leakage inductor is electronically connected between the first end and the third end of the primary leakage inductor module;
the second primary leakage inductor is electronically connected between the second end and the fourth end of the primary leakage inductor module;
the first end and the third end of the secondary leakage inductor module are electronically connected together;
the second secondary leakage inductor is electronically connected between the second end and the fourth end of the secondary leakage inductor module.

14. The transformer simulating circuit as claimed in claim 1, wherein:
the primary leakage inductor module comprises a first primary leakage inductor;
the secondary leakage inductor module comprises a first secondary leakage inductor and a second secondary leakage inductor;
the first primary leakage inductor is electronically connected between the first end and the third end of the primary leakage inductor module;
the second end and the fourth end of the primary leakage inductor module are electronically connected together;
the first secondary leakage inductor is electronically connected between the first end and the third end of the secondary leakage inductor module;
the second secondary leakage inductor is electronically connected between the second end and the fourth end of the secondary leakage inductor module.

15. The transformer simulating circuit as claimed in claim 1, wherein:
the primary leakage inductor module comprises a second primary leakage inductor;
the secondary leakage inductor module comprises a first secondary leakage inductor and a second secondary leakage inductor;
the first end and the third end of the primary leakage inductor module are electronically connected together;
the second primary leakage inductor is electronically connected between the second end and the fourth end of the primary leakage inductor module;
the first secondary leakage inductor is electronically connected between the first end and the third end of the secondary leakage inductor module;
the second secondary leakage inductor is electronically connected between the second end and the fourth end of the secondary leakage inductor module.

16. The transformer simulating circuit as claimed in claim 1, wherein:
the primary leakage inductor module comprises a first primary leakage inductor and a second primary leakage inductor;
the secondary leakage inductor module comprises a first secondary leakage inductor and a second secondary leakage inductor;
the first primary leakage inductor is electronically connected between the first end and the third end of the primary leakage inductor module;
the second primary leakage inductor is electronically connected between the second end and the fourth end of the primary leakage inductor module;
the first secondary leakage inductor is electronically connected between the first end and the third end of the secondary leakage inductor module;
the second secondary leakage inductor is electronically connected between the second end and the fourth end of the secondary leakage inductor module.

17. A simulating method of a transformer, comprising steps of:
providing a primary winding; wherein the primary winding comprises a first terminal and a second terminal;
providing a primary core-loss resistor;
providing a primary intra-winding capacitor;
providing a magnetizing inductor; wherein the magnetizing inductor is electronically connected to the primary core-loss resistor and the primary intra-winding capacitor in parallel;
providing a primary leakage inductor module; wherein the primary leakage inductor module comprises a first end, a second end, a third end, and a fourth end, the first end and the second end of the primary leakage inductor module are respectively electronically connected to two ends of the primary intra-winding capacitor, and the third end and the fourth end of the primary leakage inductor module are respectively electronically connected to the first terminal and the second terminal of the primary winding;
providing a primary winding resistor; wherein the primary winding resistor comprises an end electronically connected to the first end of the primary leakage inductor module;
providing a secondary winding resistor;
providing a secondary leakage inductor module; wherein the secondary leakage inductor module comprises a first end, a second end, a third end, and a fourth end, and the third end of the secondary leakage inductor module is electronically connected to an end of the secondary winding resistor;
providing a secondary winding; wherein the secondary winding is coupled with the primary winding, and comprises a first terminal and a second terminal; wherein the first terminal and the second terminal of the secondary winding are respectively electronically connected to the first end and the second end of the secondary leakage inductor module ;
providing a secondary intra-winding capacitor; wherein the secondary intra-winding capacitor is electronically connected between the third end and the fourth end of the secondary leakage inductor module;
providing a first coupling capacitor; wherein the first coupling capacitor is electronically connected between the first end of the primary leakage inductor module and the third end of the secondary leakage inductor module; and
providing a second coupling capacitor; wherein the second coupling capacitor is electronically connected between the second end of the primary leakage inductor module and the fourth end of the secondary leakage inductor module;
forming a transformer simulating circuit; and
implementing the transformer simulating circuit to simulate the transformer.

18. The simulating method of the transformer as claimed in claim 17, wherein:
the primary leakage inductor module comprises a first primary leakage inductor;
the first primary leakage inductor is electronically connected between the first end and the third end of the primary leakage inductor module;
the second end and the fourth end of the primary leakage inductor module are electronically connected together;
the first end and the third end of the secondary leakage inductor module are electronically connected together;
the second end and the fourth end of the secondary leakage inductor module are electronically connected together.

19. The simulating method of the transformer as claimed in claim 17, wherein:
the primary leakage inductor module comprises a second primary leakage inductor;
the second primary leakage inductor is electronically connected between the second end and the fourth end of the primary leakage inductor module;
the first end and the third end of the primary leakage inductor module are electronically connected together;
the first end and the third end of the secondary leakage inductor module are electronically connected together;
the second end and the fourth end of the secondary leakage inductor module are electronically connected together.

20. The simulating method of the transformer as claimed in claim 17, wherein:
the secondary leakage inductor module comprises a first secondary leakage inductor;
the first end and the third end of the primary leakage inductor module are electronically connected together;
the second end and the fourth end of the primary leakage inductor module are electronically connected together;
the first secondary leakage inductor is electronically connected between the first end and the third end of the secondary leakage inductor module;
the second end and the fourth end of the secondary leakage inductor module are electronically connected together.

21. The simulating method of the transformer as claimed in claim 17, wherein:
the secondary leakage inductor module comprises a second primary leakage inductor;
the first end and the third end of the primary leakage inductor module are electronically connected together;
the second end and the fourth end of the primary leakage inductor module are electronically connected together;
the second secondary leakage inductor is electronically connected between the second end and the fourth end of the secondary leakage inductor module;
the first end and the third end of the secondary leakage inductor module are electronically connected together.

22. The simulating method of the transformer as claimed in claim 17, wherein:
the primary leakage inductor module comprises a first primary leakage inductor and a second primary leakage inductor;
the first primary leakage inductor is electronically connected between the first end and the third end of the primary leakage inductor module;
the second primary leakage inductor is electronically connected between the second end and the fourth end of the primary leakage inductor module;
the first end and the third end of the secondary leakage inductor module are electronically connected together;
the second end and the fourth end of the secondary leakage inductor module are electronically connected together.

23. The simulating method of the transformer as claimed in claim 17, wherein:
the primary leakage inductor module comprises a first primary leakage inductor;
the secondary leakage inductor module comprises a first secondary leakage inductor;
the first primary leakage inductor is electronically connected between the first end and the third end of the primary leakage inductor module;
the second end and the fourth end of the primary leakage inductor module are electronically connected together;
the first secondary leakage inductor is electronically connected between the first end and the third end of the secondary leakage inductor module;
the second end and the fourth end of the secondary leakage inductor module are electronically connected together.

24. The simulating method of the transformer as claimed in claim 17, wherein:
the primary leakage inductor module comprises a first primary leakage inductor;
the secondary leakage inductor module comprises a second secondary leakage inductor;
the first primary leakage inductor is electronically connected between the first end and the third end of the primary leakage inductor module;
the second end and the fourth end of the primary leakage inductor module are electronically connected together;
the first end and the third end of the secondary leakage inductor module are electronically connected together;
the second secondary leakage inductor is electronically connected between the second end and the fourth end of the secondary leakage inductor module.

25. The simulating method of the transformer as claimed in claim 17, wherein:
the primary leakage inductor module comprises a second primary leakage inductor;
the secondary leakage inductor module comprises a first secondary leakage inductor;
the first end and the third end of the primary leakage inductor module are electronically connected together;
the second primary leakage inductor is electronically connected between the second end and the fourth end of the primary leakage inductor module;
the first secondary leakage inductor is electronically connected between the first end and the third end of the secondary leakage inductor module;
the second end and the fourth end of the secondary leakage inductor module are electronically connected together.

26. The simulating method of the transformer as claimed in claim 17, wherein:
the primary leakage inductor module comprises a second primary leakage inductor;
the secondary leakage inductor module comprises a second secondary leakage inductor;
the first end and the third end of the primary leakage inductor module are electronically connected together;
the second primary leakage inductor is electronically connected between the second end and the fourth end of the primary leakage inductor module;
the first end and the third end of the secondary leakage inductor module are electronically connected together;
the second secondary leakage inductor is electronically connected between the second end and the fourth end of the secondary leakage inductor module.

27. The simulating method of the transformer as claimed in claim 17, wherein:
the secondary leakage inductor module comprises a first secondary leakage inductor and a second secondary leakage inductor;
the first end and the third end of the primary leakage inductor module are electronically connected together;
the second end and the fourth end of the primary leakage inductor module are electronically connected together;
the first secondary leakage inductor is electronically connected between the first end and the third end of the secondary leakage inductor module;
the second secondary leakage inductor is electronically connected between the second end and the fourth end of the secondary leakage inductor module.

28. The simulating method of the transformer as claimed in claim 17, wherein:
the primary leakage inductor module comprises a first primary leakage inductor and a second primary leakage inductor;
the secondary leakage inductor module comprises a first secondary leakage inductor;
the first primary leakage inductor is electronically connected between the first end and the third end of the primary leakage inductor module;
the second primary leakage inductor is electronically connected between the second end and the fourth end of the primary leakage inductor module;
the first secondary leakage inductor is electronically connected between the first end and the third end of the secondary leakage inductor module;
the second end and the fourth end of the secondary leakage inductor module are electronically connected together.

29. The simulating method of the transformer as claimed in claim 17, wherein:
the primary leakage inductor module comprises a first primary leakage inductor and a second primary leakage inductor, and the secondary leakage inductor module comprises a second secondary leakage inductor;
the first primary leakage inductor is electronically connected between the first end and the third end of the primary leakage inductor module;
the second primary leakage inductor is electronically connected between the second end and the fourth end of the primary leakage inductor module;
the first end and the third end of the secondary leakage inductor module are electronically connected together;
the second secondary leakage inductor is electronically connected between the second end and the fourth end of the secondary leakage inductor module.

30. The simulating method of the transformer as claimed in claim 17, wherein:
the primary leakage inductor module comprises a first primary leakage inductor;
the secondary leakage inductor module comprises a first secondary leakage inductor and a second secondary leakage inductor;
the first primary leakage inductor is electronically connected between the first end and the third end of the primary leakage inductor module;
the second end and the fourth end of the primary leakage inductor module are electronically connected together;
the first secondary leakage inductor is electronically connected between the first end and the third end of the secondary leakage inductor module;
the second secondary leakage inductor is electronically connected between the second end and the fourth end of the secondary leakage inductor module.

31. The simulating method of the transformer as claimed in claim 17, wherein:
the primary leakage inductor module comprises a second primary leakage inductor;
the secondary leakage inductor module comprises a first secondary leakage inductor and a second secondary leakage inductor;
the first end and the third end of the primary leakage inductor module are electronically connected together;
the second primary leakage inductor is electronically connected between the second end and the fourth end of the primary leakage inductor module;
the first secondary leakage inductor is electronically connected between the first end and the third end of the secondary leakage inductor module;
the second secondary leakage inductor is electronically connected between the second end and the fourth end of the secondary leakage inductor module.

32. The simulating method of the transformer as claimed in claim 17, wherein:
the primary leakage inductor module comprises a first primary leakage inductor and a second primary leakage inductor;
the secondary leakage inductor module comprises a first secondary leakage inductor and a second secondary leakage inductor;
the first primary leakage inductor is electronically connected between the first end and the third end of the primary leakage inductor module;
the second primary leakage inductor is electronically connected between the second end and the fourth end of the primary leakage inductor module;
the first secondary leakage inductor is electronically connected between the first end and the third end of the secondary leakage inductor module;
the second secondary leakage inductor is electronically connected between the second end and the fourth end of the secondary leakage inductor module.
